(19) United States
(12) Patent Application Publication
(10) Pub. No.: US 2021/0050922 A1
(43) Pub. Date: Feb. 18, 2021

(54) METHOD OF BONDING OPTICAL COMPONENTS OF OPTICAL TRANSCEIVER

(71) Applicant: Prime World International Holdings Ltd., New Taipei City (TW)

(72) Inventors: Chin-Lung CHENG, New Taipei City (TW); Chien Yin TUNG, New Taipei City (TW)

(21) Appl. No.: 16/540,751

(22) Filed: Aug. 14, 2019

(51) Int. Cl. H04B 10/40; H01S 5/022; H01L 31/02; H01L 31/12; H01L 31/0232; H01L 23/544

(52) U.S. Cl. CPC H04B 10/40; H01S 5/02252; H01L 31/02005; H01L 2223/54426; H01L 31/02325; H01L 23/544; H01S 5/02268; H01L 31/12

(57) ABSTRACT

A method of bonding optical components of an optical transceiver is disclosed. An electro-optical assembly is provided. The electro-optical assembly includes a substrate and two first optical components bonded with the substrate. A reference pair of coordinates is obtained according to a geometric factor related to the first optical components. At least one second optical component is bonded with the substrate according to the reference pair of coordinates.

### BACKGROUND

### 1. Technical Field

The present disclosure relates to a bonding method, more particularly to a method of bonding optical components of an optical transceiver.

### 2. Related Art

Optical transceivers are generally installed in electronic communication facilities in modern high-speed communication networks. In order to make flexible the design of an electronic communication facility and less burdensome the maintenance of the same, an optical transceiver is inserted into a corresponding cage that is disposed in the communication facility in a pluggable manner. In order to define the electrical-to-mechanical interface of the optical transceiver and the corresponding cage, different form factors such as XFP (10 Gigabit Small Form Factor Pluggable) used in 10 GB/s communication rate, QSFP (Quad Small Form-factor Pluggable), or others at different communication rates have been made available.

As to the optical components in the optical transceiver, some optical components are bonded on a substrate, such as a circuit board, to function as optical transmitters or optical receivers. Generally, the optical components are bonded on the substrate by automatic manufacturing equipments.

### SUMMARY

According to one aspect of the present disclosure, a method of bonding optical components of an optical transceiver is disclosed. An electro-optical assembly is provided. The electro-optical assembly includes a substrate and two first optical components bonded with the substrate. A reference pair of coordinates is obtained according to a geometric factor related to the first optical components. The method may further include bonding a second optical component is bonded with the substrate according to the reference pair of coordinates.

According to another aspect of the present disclosure, a method of bonding optical components of an optical transceiver is disclosed. The disclosed method may include providing an electro-optical assembly including a substrate and a plurality of first optical components bonded with the substrate. The method may further include obtaining a reference pair of coordinates according to a geometric factor related to the first optical components. The method may further include bonding a second optical component with the substrate according to the reference pair of coordinates.

### BRIEF DESCRIPTION OF THE DRAWINGS

The present disclosure will become more fully understood from the detailed description given below and the accompanying drawings which are given by way of illustration only and thus are not intending to limit the present disclosure and wherein:

FIG. 1 is a perspective view of an electro-optical assembly in an optical transceiver according to a first embodiment of the present disclosure;

FIG. 2 is an exploded view of the electro-optical assembly in FIG. 1;

FIG. 3 through FIG. 8 are schematic views of bonding optical components of the electro-optical assembly in FIG. 1;

FIG. 9 is a perspective view of an electro-optical assembly of an optical transceiver according to a second embodiment of the present disclosure;

FIG. 10 is a schematic view of bonding optical components of the electro-optical assembly in FIG. 9; and

FIG. 11 is a perspective view of bonding optical components of an electro-optical assembly according to a third embodiment of the present disclosure.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawings.

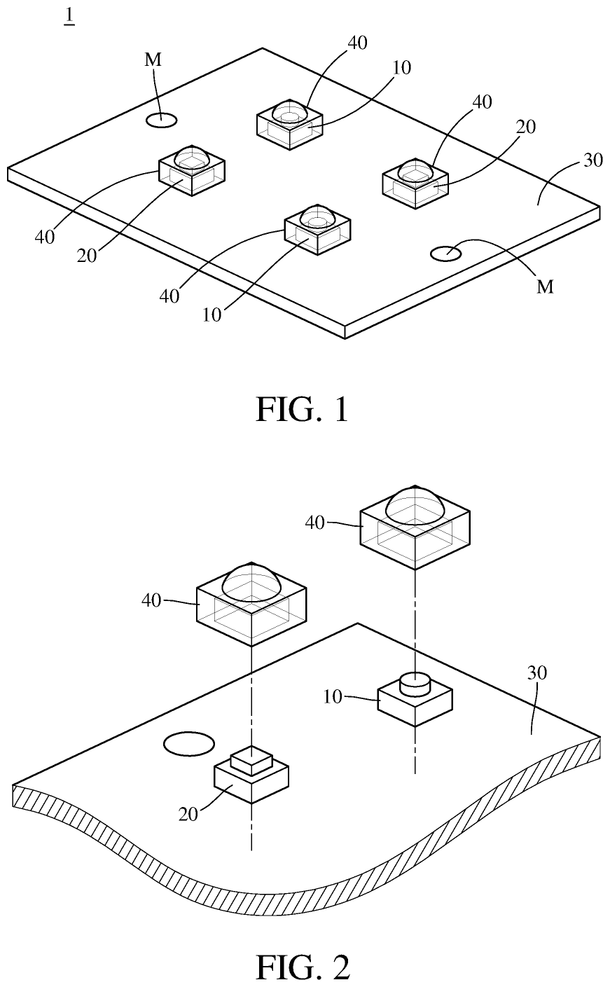

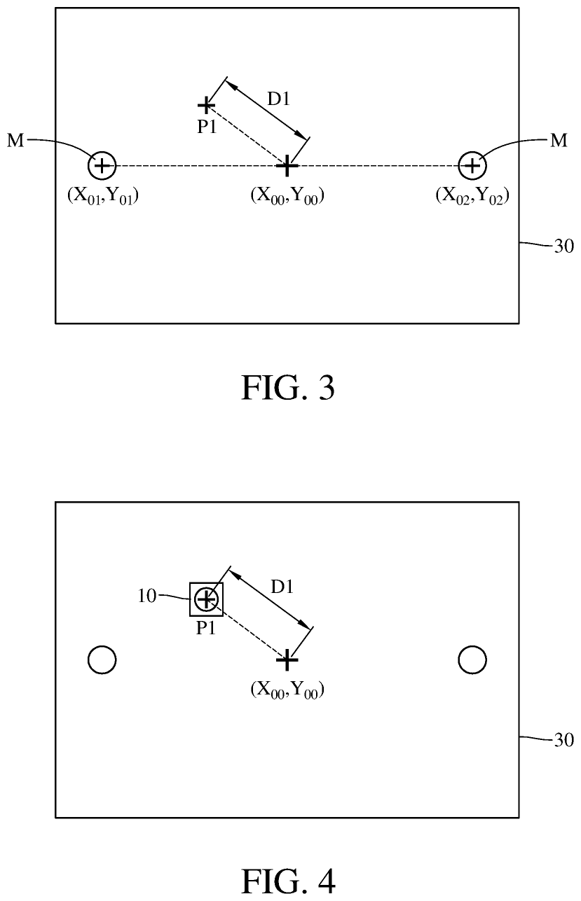

FIG. 1 is a perspective view of an electro-optical assembly of an optical transceiver according to a first embodiment of the present disclosure. FIG. 2 is an exploded view of the electro-optical assembly in FIG. 1. In this embodiment, an electro-optical assembly 1 in an optical transceiver includes two first optical components 10, two second optical components 20, a substrate 30, and a plurality of optical lenses 40.

Each of the first optical components 10 and the second optical components 20, for example, is an active optical component such as a vertical-cavity surface-emitting laser (VCSEL) or a photodiode. The VCSEL is an optical transmitter in a transmitter optical subassembly (TOSA) of the optical transceiver, and the photodiode serves as an optical receiver in a receiver optical subassembly (ROSA) of the optical transceiver. In this embodiment, each of the first optical components 10 is a VCSEL, and each of the second optical components 20 is a photodiode. In some embodiment, the first optical components 10 and the second optical components 20 are all VCSELs or all photodiodes. In some other embodiments, the two first optical components 10 are a VCSEL and a photodiode, respectively.

The substrate 30, for example, is a circuit board accommodated in a housing of the optical transceiver. The first optical components 10 and the second optical components 20 are bonded with the substrate 30.

The optical lenses 40 are bonded with the substrate 30. The optical lenses 40 are arranged with some optical lenses 40 located above respective first optical components 10 and some other optical lenses 40 located above respective second optical components 20. Each of the optical lenses 40 is an optional element in the electro-optical assembly 1.

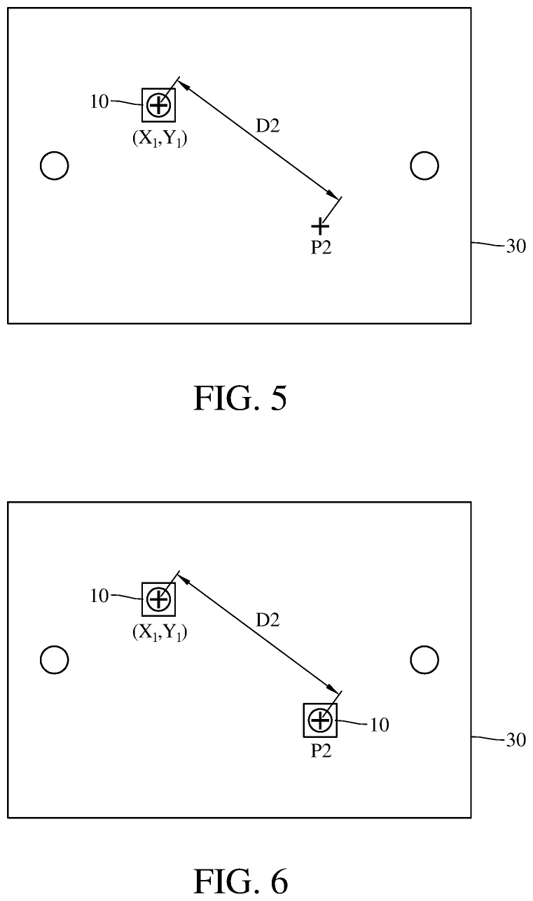

In this embodiment, a method of bonding the first optical components 10 and the second optical components 20 is disclosed as follows. FIGS. 3 to 8 are schematic views of bonding optical components of the electro-optical assembly in FIG. 1. In this embodiment, the method of bonding the first optical components 10 and the second optical components 20 can be achieved by an automation manufacturing equipment (not shown in the drawings) in which an image processing software is installed to help facilitate the bonding.

At least two alignment marks M are formed on the substrate 30. The alignment mark M, for example, is a through hole or a blind hole formed on the substrate 30. In one implementation, two of the alignment marks M are specified with original pairs of coordinates such as (X₀₁, Y₀₁) and (X₀₂, Y₀₂), and a reference pair of coordinates, such as (X₀₀, Y₀₀), is obtained according to the original pairs of coordinates (X₀₁, Y₀₁) and (X₀₂, Y₀₂).

Specifically, as shown in FIG. 3, the alignment marks M can be recognized by a camera electrically coupled with the automation manufacturing equipment. The original pairs of coordinates (X₀₁, Y₀₁) and (X₀₂, Y₀₂) can be specified by the image processing software, and the reference pair of coordinates (X₀₀, Y₀₀) can be obtained on basis of the following condition: X₀₀=(Y₀₁+Y₀₂)/2; and Y₀₀=(Y₀₁+Y₀₂)/2.

After the reference pair of coordinates (X₀₀, Y₀₀) is obtained, one first optical component 10 is bonded with the substrate 30 according to the reference pair of coordinates (X₀₀, Y₀₀).

Specifically, a non-bonded first optical component 10 is firstly recognized by the camera, and a distance between the non-bonded first optical component 10 and the reference pair of coordinates (X₀₀, Y₀₀) is calculated by the processing unit of the automation manufacturing equipment. As shown in FIG. 3 and FIG. 4, if the distance exceeds a predetermined distance D1 between a bonding position P1 and the reference pair of coordinates (X₀₀, Y₀₀), the non-bonded first optical component 10 is moved to the bonding position P by a clamp, such that the non-bonded first optical component 10 is spaced apart from the reference pair of coordinates (X₀₀, Y₀₀) by the predetermined distance D1. The first optical component 10 is then bonded with the substrate 30 at the bonding position P1.

After one of the first optical components 10 is bonded, the bonded first optical component 10 is specified with a reference pair of coordinates such as (X₁, Y₁), and another first optical component 10 is bonded with the substrate 30 according to the reference pair of coordinates (X₁, Y₁).

Specifically, another non-bonded first optical component 10 is recognized by the camera, and then a distance between the non-bonded first optical component 10 and the reference pair of coordinates (X₁, Y₁) is calculated by the automation manufacturing equipment as well. As shown in FIG. 5 and FIG. 6, the reference pair of coordinates (X₁, Y₁) can be specified by the image processing software. If the distance exceeds a predetermined distance D2 between a bonding position P2 and the reference pair of coordinates (X₁, Y₁), the non-bonded first optical component 10 is moved to the bonding position P2 by the clamp of the automation manufacturing equipment, such that another non-bonded first optical component 10 is spaced apart from the reference pair of coordinates (X₁, Y₁) by the predetermined distance D2. The first optical component 10 is then bonded with the substrate 30 at the bonding position P2.

Next, a reference pair of coordinates, such as (Xₐ, Yₐ), is obtained according to a geometric factor related to the two first optical components 10.

Specifically, as shown in FIG. 7, the first optical component 10 bonded at the bonding position P2 in FIG. 6 is specified with an original pair of coordinates, such as (X₂, Y₂), by the image processing software, and the pair of coordinates (X₁, Y₁) is considered as an original pair of coordinates in order to obtain the reference pair of coordinates (Xₐ, Yₐ). In this embodiment, said geometric factor is a connection line L passing through the original pairs of coordinates (X₁, Y₁) and (X₂, Y₂). The reference pair of coordinates (Xₐ, Yₐ) is located on the connection line L. The two first optical components 10 are symmetrically arranged with respect to the reference pair of coordinates (Xₐ, Yₐ), and the reference pair of coordinates (Xₐ, Yₐ) is equally spaced apart from each of the original pairs of coordinates (X₁, Y₁) and (X₂, Y₂). More specifically, in this embodiment, the reference pair of coordinates is (Xₐ, Yₐ) is determined according to the following conditions: Xₐ=(X₂−X₁)/2 and Yₐ=(Y₂−Y₁)/2.

It is worth noting that the position of the reference pair of coordinates (Xₐ, Yₐ) is not limited by the above discussion. In some embodiments, the reference pair of coordinates (Xₐ, Yₐ) can be any point on the connection line L and located between the original pairs of coordinates (X₁, Y₁) and (X₂, Y₂).

Furthermore, the module shown in FIG. 7, in which two first optical components 10 have been bonded with the substrate 30 while no second optical component 20 bonded with the substrate 30, is considered as a semi-finished electro-optical assembly SA in this embodiment.

Next, the two second optical components 20 are bonded with the substrate 30 according to the reference pair of coordinates (Xₐ, Yₐ).

Specifically, two non-bonded second optical components 20 are recognized by the camera, and then a distance between each non-bonded second optical component 20 and the reference pair of coordinates (Xₐ, Yₐ) is calculated. As shown in FIG. 8, if the distance exceeds a predetermined distance D3 between a bonding positions P3 and the reference pair of coordinates (Xₐ, Yₐ), the non-bonded second optical component 20 is moved to the bonding position P3 by the clamp of the automation manufacturing equipment armed with computational capability for the purpose of the present disclosure. When the two second optical components 20 are respectively at the two bonding positions P3, each second optical component 20 is spaced apart from the reference pair of coordinates (Xₐ, Yₐ) by the predetermined distance D3. The second optical components 20 are then bonded with the substrate 30 at the bonding positions P3. The second optical components 20 are symmetrically arranged with respect to the reference pair of coordinates (Xₐ, Yₐ). It is worth noting that the number of the second optical components 20 is not limited by the above discussion.

In this embodiment, each of the first optical components 10 and the second optical components 20 is bonded by a process such chip on board (COB), wire bonding or surface mount technology (SMT).

Moreover, as shown in FIG. 8, in this embodiment, each of the original pairs of coordinates (X₁, Y₁) and (X₂, Y₂) corresponds to an active region 110 of the first optical component 10. More specifically, the original pair of the coordinates (X₁, Y₁) or (X₂, Y₂) may just correspond to the center of the active region 110 of the first optical component 10. It is noted that a reference point for specifying the first optical component 10 is not limited by the above discussion. In some embodiments, the original pair of coordinates may correspond to a vertex of the first optical component 10, or a mark on the top surface of the first optical component 10.

When multiple optical lenses 40 are required to be disposed on the substrate 30, they are located above respective first optical components 10 and respective second optical components 20.

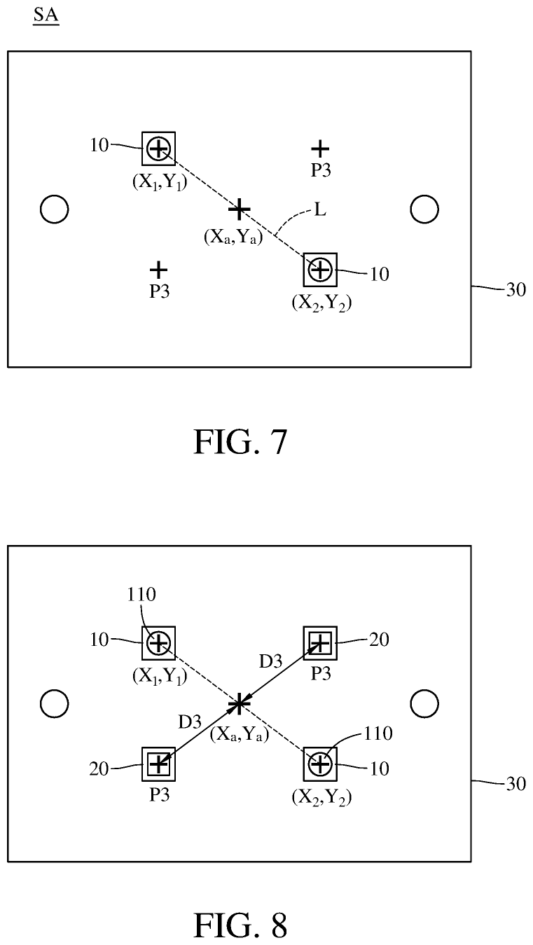

Another method of bonding optical components is described in the following embodiment. Please refer to FIG. 9, which is a perspective view of an electro-optical assembly of an optical transceiver according to a second embodiment of the present disclosure. In this embodiment, an electro-optical assembly 1a in an optical transceiver includes three first optical components 11, a second optical component 21 and a substrate 31. The first optical components 11 and the second optical component 21 are bonded with the substrate 31.

A method of bonding the second optical component 20 is described as follows. Firstly, a semi-finished electro-optical assembly is provided. The semi-finished electro-optical assembly includes the substrate 31 and the first optical components 11 bonded with the substrate 31, while the second optical component 20 has not been bonded with the substrate 31 yet. The first optical components 11 are spaced apart from each other.

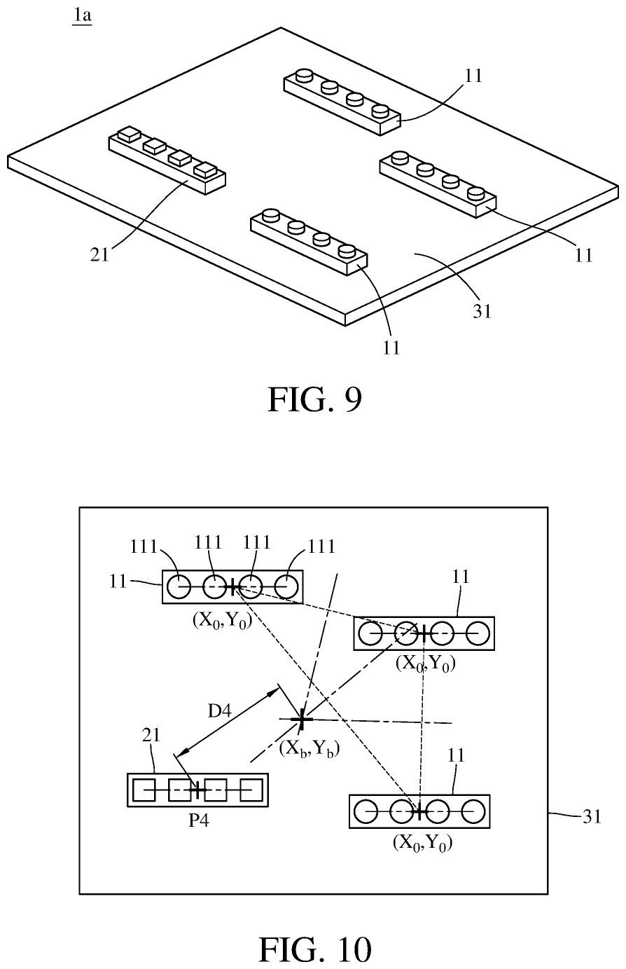

FIG. 10 is a schematic view of bonding optical components of the electro-optical assembly in FIG. 9. A reference pair of coordinates (X_{b}, Y_{b}) is obtained according to a geometric factor related to the first optical components 11. Each of the first optical components 11 is specified with an original pair of coordinates (X₀, Y₀) by the image processing software. In this embodiment, the geometric factor is a geometric center of the original pairs of coordinates (X₀, Y₀).

Specifically, as shown in FIG. 10, the three original pairs of coordinates (X₀, Y₀) are considered as three vertices of a triangle. The geometric center of the original pairs of coordinates (X₀, Y₀) is the incenter of the triangle. As such, the incenter of the triangle is specified with the reference pair of coordinates (X_{b}, Y_{b}). It is worth noting that the position of the reference pair of coordinates (X_{b}, Y_{b}) is not limited by the above discussion. In some embodiments, the centroid, the circumcenter or the orthocenter can be specified with the reference pair of coordinates (X_{b}, Y_{b}).

The second optical component 21 is bonded with the substrate 31 according to the reference pair of coordinates (X_{b}, Y_{b}). Specifically, the non-bonded second optical components 21 is recognized by the camera, and then a distance between the second optical component 21 and the reference pair of coordinates (X_{b}, Y_{b}) is calculated. If the distance exceeds a predetermined distance D4 between a bonding positions P4 and the reference pair of coordinates (X_{b}, Y_{b}), the non-bonded second optical component 21 is moved to the bonding position P4 by the clamp of the automation manufacturing equipment. The second optical component 21 at the bonding position P4 is spaced apart from the reference pair of coordinates (X_{b}, Y_{b}) by the predetermined distance D4. The second optical component 21 is then bonded with the substrate 31 at the bonding position P4. It is worth noting that the number of the second optical components 21 is not limited by the above discussion.

In this embodiment, each of the original pairs of coordinates (X₀, Y₀) corresponds to a center of the active regions 111 of the first optical components 11. More specifically, referring to FIG. 10, the active regions 111 are linearly arranged, and one of the active regions 111 closest to the center of the first optical component 11 could be specified with the original pair of coordinates (X₀, Y₀).

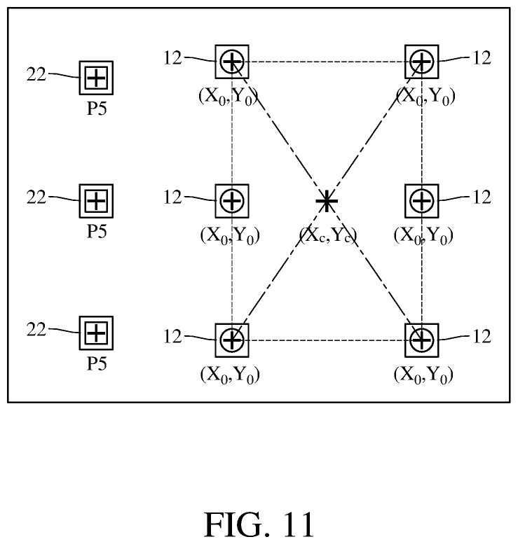

Please refer to FIG. 11, which is a perspective view of bonding optical components of an electro-optical assembly according to a third embodiment of the present disclosure. In this embodiment, an electro-optical assembly in an optical transceiver includes six first optical components 12, three second optical components 22, and a substrate 32. A method of bonding the second optical components 22 is described as follows.

First, a semi-finished electro-optical assembly is provided. The semi-finished electro-optical assembly includes the substrate 32 and the first optical components 12 bonded with the substrate 32, while the second optical components 22 have not bonded with the substrate 32 yet. The first optical components 12 are spaced apart from each other.

Next, a reference pair of coordinates (X_{c}, Y_{c}) is obtained according to a geometric factor related to the first optical components 12. Each of the first optical components 12 is specified with an original pair of coordinates (X₀, Y₀). In this embodiment, the geometric factor is a geometric center of the original pairs of coordinates (X₀, Y₀).

Specifically, among the six original pairs of coordinates (X₀, Y₀), four original pairs of coordinates (X₀, Y₀) are considered as four vertices of a rectangle. The geometric center of the original pairs of coordinates (X₀, Y₀) is the center of the rectangle. Consequently, the center of the rectangle is specified with the reference pair of coordinates (X_{c}, Y_{c}).

The second optical component 22 is bonded with the substrate 32 according to the reference pair of coordinates (X_{c}, Y_{c}). Specifically, the non-bonded second optical components 22 are recognized by the camera, and then a distance between the second optical component 22 and the reference pair of coordinates (X_{c}, Y_{c}) is calculated. If the distance exceeds a predetermined distance between a bonding positions P5 and the reference pair of coordinates (X_{c}, Y_{c}), the non-bonded second optical component 22 is moved to the bonding position P5. The second optical component 22 is then bonded with the substrate 32 at the bonding position P5. It is worth noting that the number of the second optical components 22 is not limited by the above discussion.

At the time the optical transceiver is to be packaged, when bonding the optical components with the substrate by using a conventional approach, each of the bonding positions is determined according to a single reference pair of coordinates. For any optical component to be bonded with the substrate, the bonding position is determined according to the same reference pair of coordinates, disregarding the sequence of the bonding of the optical components.

However, according to the present disclosure, the reference pair of coordinates for determining the bonding position varies with the geometric factor of the optical components which have been bonded with the substrate. More specifically, the reference pair of coordinates can vary with the number of the bonded optical components or the arrangement of the bonded optical components. Therefore, the present disclosure might help eliminate is the positioning deviation in the bonding process, improving the manufacturing yield.

The embodiments are chosen and described in order to best explain the principles of the present disclosure and its practical applications, to thereby enable others skilled in the art to best utilize the present disclosure and various embodiments with various modifications as are suited to the particular use being contemplated. It is intended that the scope of the present disclosure is defined by the following claims and their equivalents.

1. A method of bonding optical components of optical transceiver, comprising:
providing an electro-optical assembly comprising a substrate and two first optical components bonded with the substrate;
obtaining a reference pair of coordinates according to a geometric factor related to the two first optical components; and
bonding a second optical component with the substrate according to the reference pair of coordinates.

2. The method of bonding optical components according to claim 1, wherein each of the two first optical components is specified with an original pair of coordinates, and the geometric factor is a connection line passing through the original pairs of coordinates.

3. The method of bonding optical components according to claim 2, wherein one of the two original pairs of coordinates is (X₁, Y₁), the other one of the two original pairs of coordinates is (X₂, Y₂), the reference pair of coordinates is (Xₐ, Yₐ), and the following conditions are satisfied:
Xₐ=(X₂−X₁)/2; and
Yₐ=(Y₂−Y₁)/2.

4. The method of bonding optical components according to claim 2, wherein the two first optical components are symmetrically arranged with respect to the reference pair of coordinates.

5. The method of bonding optical components according to claim 4, further comprising two second optical components, wherein the two second optical components are symmetrically arranged with respect to the reference pair of coordinates.

6. The method of bonding optical components according to claim 2, wherein the original pair of coordinates corresponds to an active region of the first optical component or a center of a plurality of active regions of the first optical components.

7. The method of bonding optical components according to claim 1, wherein bonding the second optical component with the substrate according to the reference pair of coordinates comprises:
recognizing the second optical component;
if a distance between the second optical component and the reference pair of coordinates exceeds a predetermined distance, moving the second optical component to a bonding position; and
bonding the at least one second optical component with the substrate at the bonding position.

8. The method of bonding optical components according to claim 7, wherein the second optical component at the bonding position is equally spaced apart from each of the two first optical components.

9. The method of bonding optical components according to claim 1, wherein each of the first optical components is a vertical-cavity surface-emitting laser, and the second optical component is a photodiode.

10. The method of bonding optical components according to claim 1, further comprising:
bonding a plurality of optical lenses with the substrate, wherein the optical lenses are located above the first optical components and the second optical component, respectively.

11. A method of bonding optical components of optical transceiver, comprising:
providing an electro-optical assembly comprising a substrate and a plurality of first optical components bonded with the substrate;
obtaining a reference pair of coordinates according to a geometric factor related to the first optical components;
bonding a second optical component with the substrate according to the reference pair of coordinates.

12. The method of bonding optical components according to claim 11, wherein each of the first optical components is specified with an original pair of coordinates and the geometric factor is a geometric center of the original pairs of coordinates.

13. The method of bonding optical components according to claim 12, wherein the original pair of coordinates corresponds to an active region of the first optical component or a center of a plurality of active regions of the first optical components.

14. The method of bonding optical components according to claim 11, wherein bonding the second optical component with the substrate according to the reference pair of coordinates comprises:
recognizing the second optical component;
if the distance between the second optical component and the reference pair of coordinates exceeds a predetermined distance, moving the second optical component to a bonding position; and
bonding the second optical component with the substrate at the bonding position.

15. The method of bonding optical components according to claim 11, wherein the first optical components comprises at least one vertical-cavity surface-emitting laser and at least one photodiode, and the second optical component is a photodiode.
